(19) United States
(12) Patent Application Publication
(10) Pub. No.: US 2006/0023554 A1
(43) Pub. Date: Feb. 2, 2006

(54) Nonvolatile memory apparatus

(75) Inventors: Toru Matsushita, Kokubunji (JP); Kenji Kozakai, Tachikawa (JP); Hajime Tanabe, Musashino (JP); Takashi Horii, Higashimurayama (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/167,588

(22) Filed: Jun. 28, 2005

(30) Foreign Application Priority Data
Jul. 30, 2004 (JP) 2004-223077

(51) Int. Cl. G11C 8/00

(52) U.S. Cl. 365/230.03

(57) ABSTRACT

A read command having designated a bank, can be inputted from outside. A read command having designated a bank can be inputted from outside while an operation for reading from a memory array to a data buffer is being performed at the bank. Further, a read command having designated a bank is inputted from outside, and a buffer read command having designated a bank is inputted from outside while an operation for reading from a memory array to a data buffer is being performed at the bank, whereby reading from the data buffer of the bank to the outside is enabled.

### CROSS-REFERENCE TO RELATED APPLICATION

The present application claims priority from Japanese patent application No. 2004-223077 filed on Jul. 30, 2004, the content of which is hereby incorporated by reference into this application.

### BACKGROUND OF THE INVENTION

The present invention relates to a semiconductor memory device and a nonvolatile memory apparatus, and particularly to a technique effective if applied to a nonvolatile memory apparatus such as a nonvolatile memory having a plural-bank configuration.

As a technique discussed by the present inventors, there is known one like a nonvolatile memory such as a flash memory or the like, wherein memory arrays each including a plurality of memory cells are divided into a plurality of banks, which are respectively equipped with decoders, data buffers, etc., and memory operations such as erasure, writing, reading, etc. are performed independently every banks. There are known various techniques for improving throughput for writing/reading of data, etc. with respect to the memory having such a plural-bank configuration.

There is known, for example, a technique wherein in a nonvolatile memory having a plural-bank configuration, a write processing region number is inputted with a write instruction command, a write start address and a write start address as starting points and thereafter write data and a write start command can sequentially be accepted by the write processing region number, and further writing into each memory cell is started in response to the write start command after write data corresponding to one write processing region is latched into one bank, and a latch operation at one bank and writing into each memory cell at other bank can be made parallel (refer to a patent document 1 (Japanese Unexamined Patent Publication No. 2003-223792)).

There is also known a technique wherein in a nonvolatile memory having a plural-bank configuration, each of banks has a memory section and two buffer sections capable of respectively storing information on access units of the memory section and thereby an interleave operation can be controlled which performs the transfer of data between one buffer section of the bank and the memory section in response to an instruction for an access operation and, in parallel with this transfer, performs the transfer of data between the other buffer section of the bank and the outside, and the speeding up of an access speed is realized by making parallel the transfer of the data between the memory section and the buffer section and the transfer of the data between the buffer section and the outside at the interleave operation (refer to a patent document 2 (Japanese Unexamined Patent Publication No. 2003-317487)). The present technique aims to continuously read different pages connected to the same word line, i.e., data stored in memory cells grouped in plural form, which cannot be read simultaneously in one read operation.

Further, there is known a technique wherein in a memory system having a plurality of nonvolatile memory chips configured in plural banks and a memory controller, the memory controller is capable of selectively giving instructions of a simultaneous write operation or an interleave write operation to the plural banks of the nonvolatile memory chips, and write operations much long with respect to a write setup time interval can completely be made parallel upon the simultaneous write operation whereas upon the interleave write operation, a write operation following the write setup can be made parallel so as to overlap with a write operation of the other bank (refer to a patent document 3 (International Patent Publication No. 03/060722, Pamphlet)).

### SUMMARY OF THE INVENTION

Meanwhile, the present inventors have discussed the above techniques for the nonvolatile memory apparatuses each having the plural-bank configuration. As a result, the following have been revealed.

When, for example, data is read from a memory array to the outside, a read address set command is issued to set a read address. When a read start command is issued, reading from the memory array to its corresponding data buffer (internal buffer) is executed. Then, a read command from the data buffer is issued in wait for completion of its reading to thereby perform reading into the outside. That is, while the operation for reading from the memory array to the data buffer was in execution, it was not possible to input the next command and output data lying in the data buffer to the outside.

While there was a bank executing the operation for reading from a memory array to its corresponding data buffer, it was not possible to output data in a data buffer corresponding to each inactive bank to the outside. Therefore, a latency time taken during the operation for reading from the memory array to the data buffer became overhead at reading of high-volume data.

These occurred because upon comparison between the write operation and the read operation of the nonvolatile memory, the read operation was relatively faster than the write operation, and there was less demand for a reduction in temporal overhead taken for the operation of reading from the memory array to the data buffer.

Therefore, an object of the present invention is to provide a technique capable of, in a nonvolatile memory apparatus having a plural-bank configuration, reducing the above overhead and improving throughput at reading of high-volume data.

The above, other objects and novel features of the present invention will become apparent from the description of the present specification and the accompanying drawings.

Summaries of typical ones of the inventions disclosed in the present application will be explained in brief as follows:

A nonvolatile memory apparatus according to the present invention is a nonvolatile memory apparatus having a plural-bank configuration, such as a flash memory and has means capable of inputting a read command having designated a first bank from outside and inputting a read command having designated a second bank from outside while a read operation from each of memory cells to its corresponding internal buffer is being performed at the first bank.

Also a nonvolatile memory apparatus according to the present invention has means capable of inputting the read command having designated the second bank from outside, inputting a buffer read command having designated the first bank from outside while an operation for reading from each of the memory cells to the corresponding internal buffer is being performed at the second bank, and thereby performing reading from the internal buffer of the first bank to the outside.

Further, a nonvolatile memory apparatus according to the present invention has means capable of inputting a write command having designated the second bank from outside while an operation for reading from each of the memory cells to its corresponding internal buffer is being performed at the first bank.

An advantageous effect obtained by a representative one of the inventions disclosed in the present application will be explained in brief as follows:

Since only a first access time is visible to the outside where a read command is issued continuously plural times, throughput at reading of high-volume data can be greatly improved.

### BRIEF DESCRIPTION OF THE DRAWINGS

FIG. 1 is a block diagram showing a configuration of a nonvolatile memory apparatus according to one embodiment of the present invention;

FIG. 2 is a timing chart illustrating a one-page cache read operation at a one-stage command buffer in the nonvolatile memory apparatus according to the one embodiment of the present invention;

FIG. 3 is a timing chart showing a one-page cache read operation at a one-stage command buffer in the nonvolatile memory apparatus according to the one embodiment of the present invention;

FIG. 4 is a timing chart depicting a one-page cache read operation at a one-stage command buffer in the nonvolatile memory apparatus according to the one embodiment of the present invention;

FIG. 5 is a timing chart showing a one-page cache read end operation in the nonvolatile memory apparatus according to the one embodiment of the present invention;

FIG. 6 is a timing chart illustrating a two-page cache read operation at a one-state command buffer in the nonvolatile memory apparatus according to the one embodiment of the present invention;

FIG. 7 is a timing chart showing a two-page cache read operation at a one-stage command buffer in the nonvolatile memory apparatus according to the one embodiment of the present invention;

FIG. 8 is a timing chart depicting a two-page cache read operation at a one-stage command buffer in the nonvolatile memory apparatus according to the one embodiment of the present invention;

FIG. 9 is a timing chart showing a two-page cache read operation at a one-stage command buffer in the nonvolatile memory apparatus according to the one embodiment of the present invention;

FIG. 10 is a timing chart depicting a two-page cache read end operation in the nonvolatile memory apparatus according to the one embodiment of the present invention;

FIG. 11 is a timing chart showing a one-page cache read operation at two-stage command buffers in the nonvolatile memory apparatus according to the one embodiment of the present invention;

FIG. 12 is a timing chart illustrating a one-page cache read operation at two-stage command buffers in the nonvolatile memory apparatus according to the one embodiment of the present invention;

FIG. 13 is a timing chart showing a two-page cache read operation at two-stage command buffers in the nonvolatile memory apparatus according to the one embodiment of the present invention;

FIG. 14 is a timing chart depicting a two-page cache read operation at two-stage command buffers in the nonvolatile memory apparatus according to the one embodiment of the present invention; and

FIG. 15 is a timing chart showing a two-page cache read operation at two-stage command buffers in the nonvolatile memory apparatus according to the one embodiment of the present invention.

### DETAILED DESCRIPTION OF THE PREFERRED EMBODIMENTS

Preferred embodiments of the present invention will hereinafter be described in detail with reference to the accompanying drawings. Incidentally, the same components or members are given the same reference numerals in principle in all the drawings for describing the preferred embodiments, and their repetitive explanations are therefore omitted.

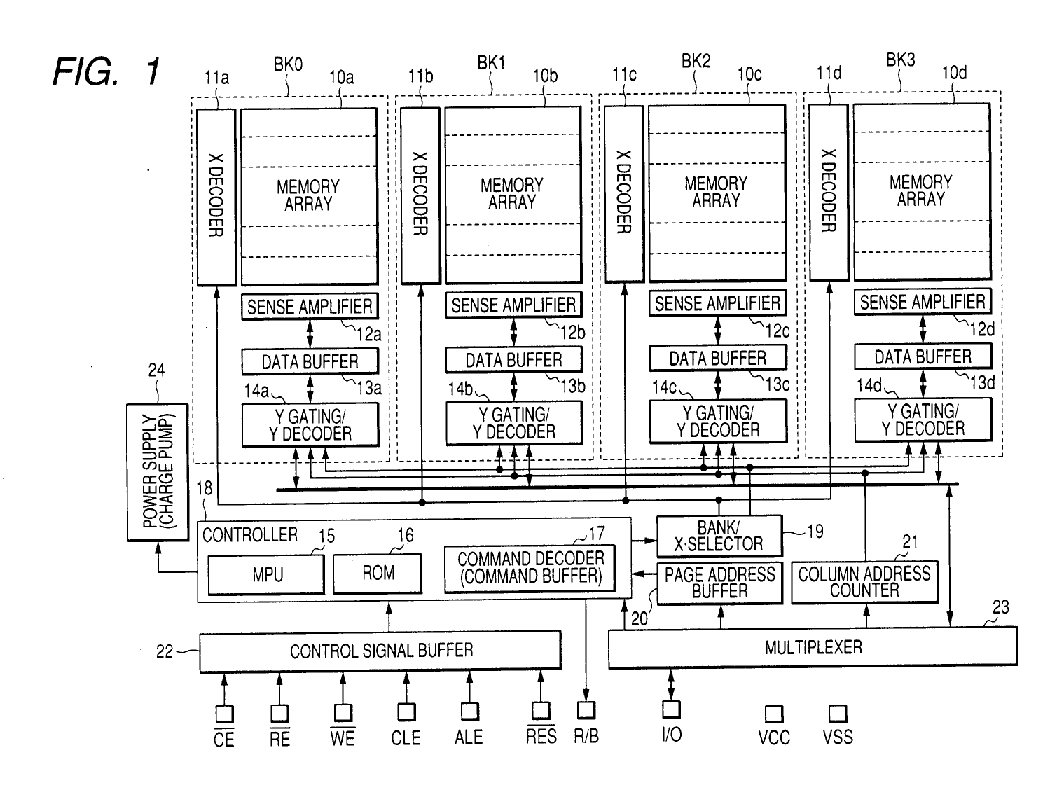

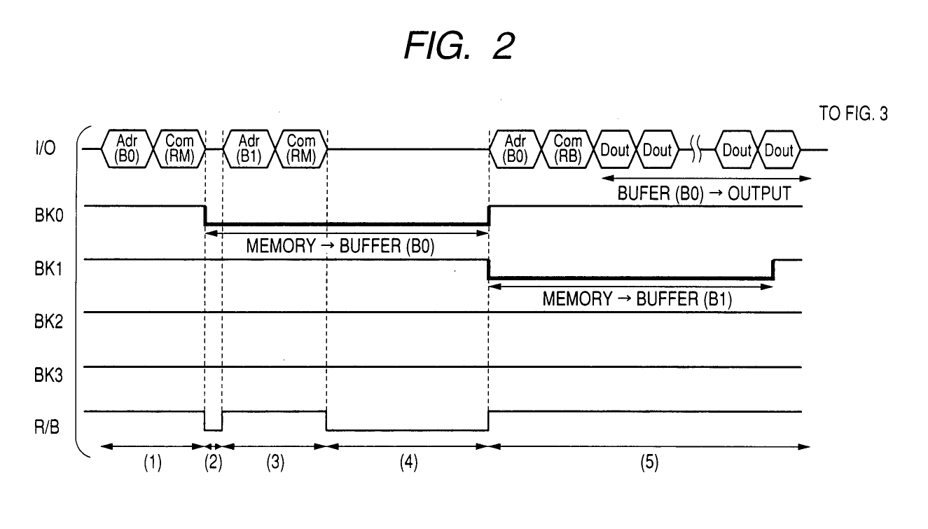

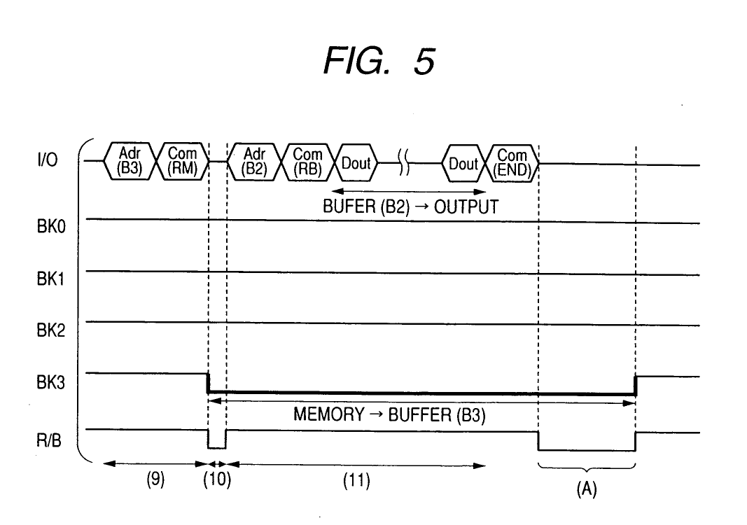

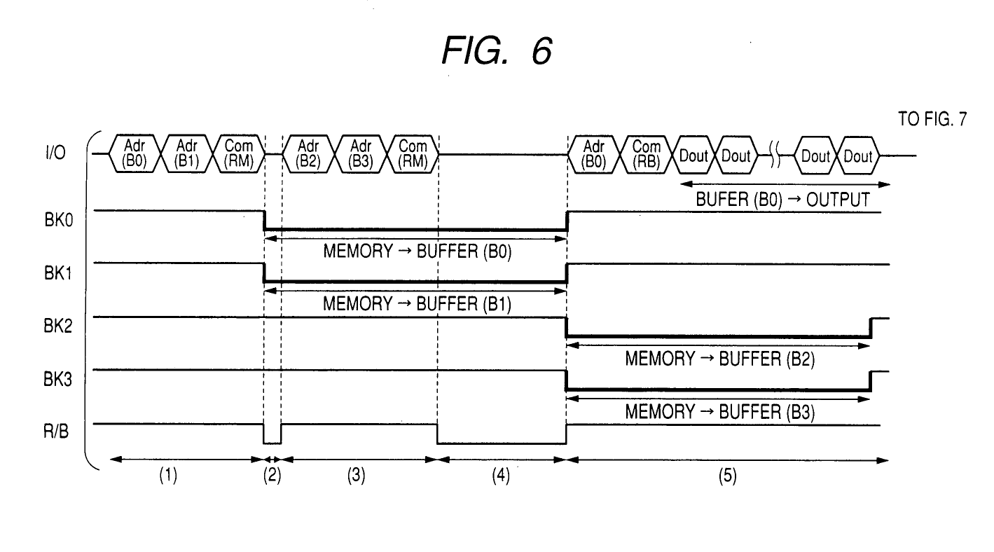

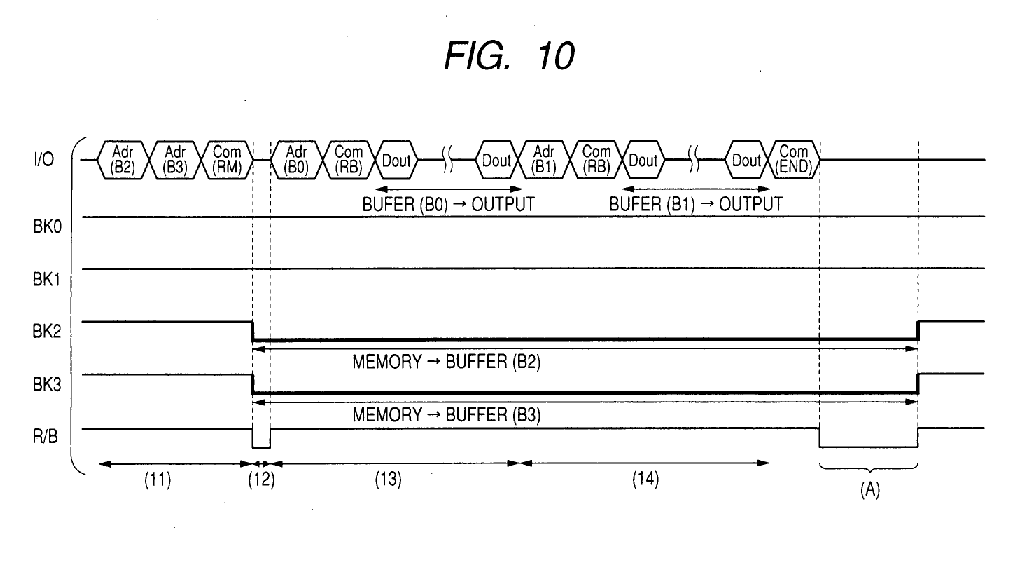

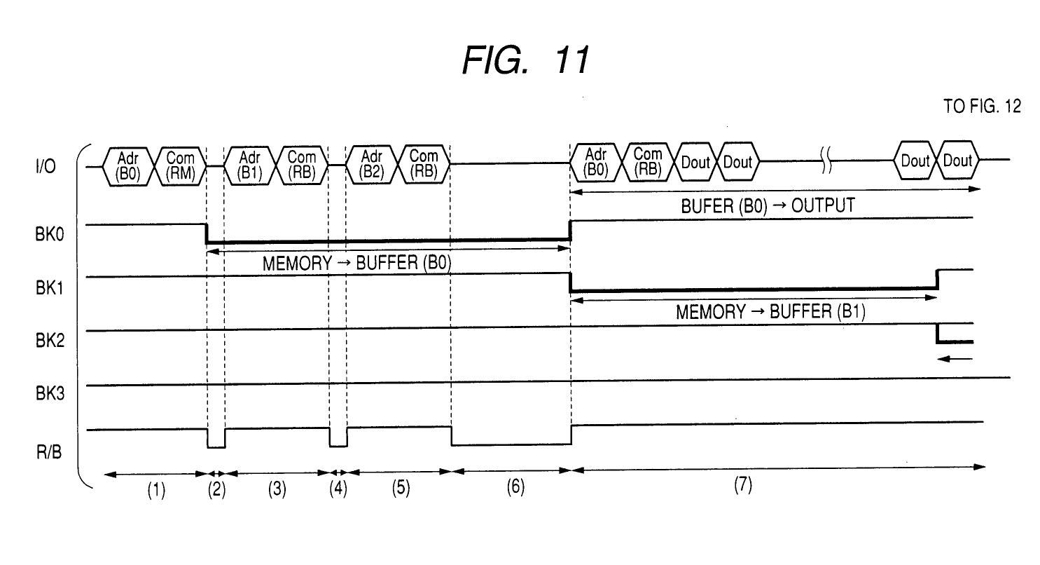

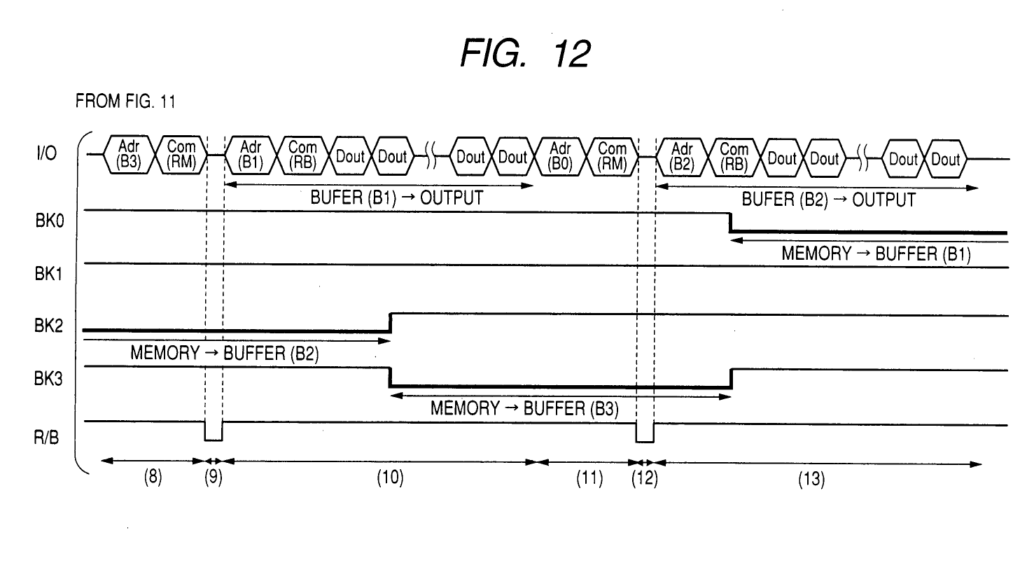

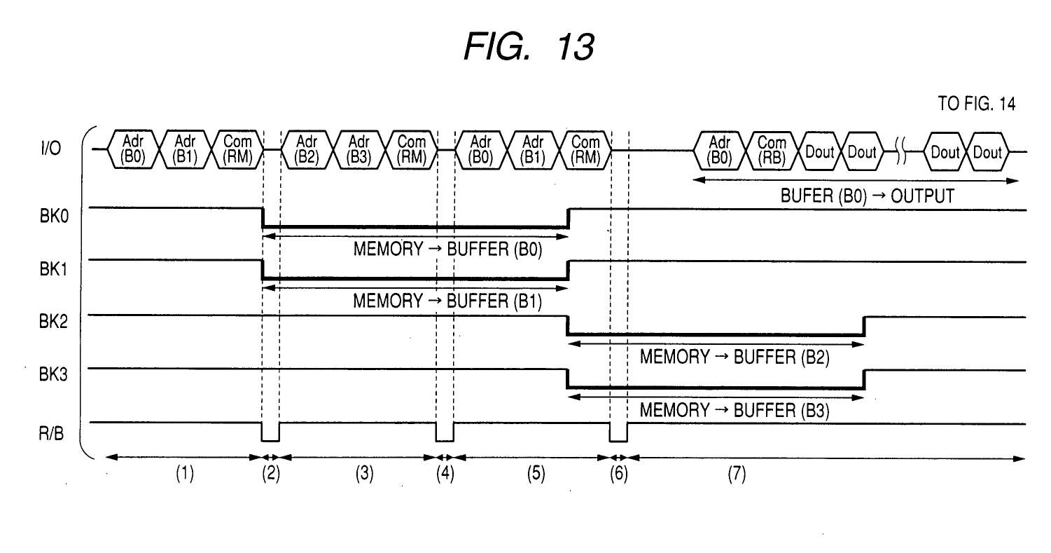

FIG. 1 is a block diagram showing a configuration of a nonvolatile memory apparatus according to one embodiment of the present invention, FIGS. 2 through 4 are respectively timing charts each showing a one-page cache read operation at a one-stage command buffer in the nonvolatile memory apparatus according to the present embodiment, FIG. 5 is a timing chart showing a one-page cache read end operation, FIGS. 6 through 9 are respectively timing charts each showing a two-page cache read operation at a one-stage command buffer, FIG. 10 is a timing chart showing a two-page cache read end operation, FIGS. 11 through 12 are respectively timing charts each showing a one-page cache read operation at two-page command buffers, and FIGS. 13 through 15 are respectively timing charts each showing a two-page cache read operation at two-stage command buffers, respectively.

One example of the configuration of the nonvolatile memory apparatus according to the present embodiment will first be explained with reference to FIG. 1. Incidentally, the present invention is not limited to it below. However, the present embodiment will be described with a 4-bank configuration as an example.

The nonvolatile memory apparatus according to the present embodiment is configured as, for example, a flash memory, and comprises four banks BK0, BK1, BK2 and BK3 which respectively comprises memory arrays 10a, 10b, 10c and 10d each including a plurality of nonvolatile memory cells, X decoders 11a, 11b, 11c and 11d, sense amplifiers 12a, 12b, 12c and 12d, data buffers 13a, 13b, 13c and 13d, Y gating/Y decoders 14a, 14b, 14c and 14d, etc.; a controller 18 which comprises an MPU 15, a ROM 16, a command decoder (including a command buffer) 17, etc. and which controls the operation of the flash memory according to external commands such as a read/program/erase, etc.; a bank/X•selector 19; a page address buffer 20; a column address counter 21; a control signal buffer 22; a multiplexer 23; a power supply (charge pump) 24; etc. The nonvolatile memory apparatus is formed over one semiconductor chip by the known semiconductor manufacturing technology.

In the present flash memory, control signals such as a chip enable signal /CE, a read enable signal /RE, a write enable signal /WE, a command latch enable signal CLE, an address latch enable signal ALE, a reset signal /RES, etc. are inputted to the control signal buffer 22 via external terminals. The output of the control signal buffer 22 is inputted to the controller 18. The controller 18 outputs a ready/busy signal R/B via an external terminal. An input/output signal I/O is inputted/outputted from and to the multiplexer 23 via an external terminal. The output of the multiplexer 23 is inputted to the controller 18, the page address buffer 20, and the column address counter 21. The output of the controller 18 is outputted to the power supply 24 and the bank/X•selector 19. The output of the page address buffer 20 is inputted to the controller 18. The output of the bank/X•selector 19 is inputted to the X decoders 11a, 11b, 11c and 11d and the Y gating/Y decoders 14a, 14b, 14c and 14d. The output of the column address counter 21 is inputted to the Y gating/Y decoders 14a, 14b, 14c and 14d. The multiplexer 23 is connected to the Y gating/Y decoders 14a, 14b, 14c and 14d via an internal data bus. Inside the banks BK0, BK1, BK2 and BK3, the Y gating/Y decoders 14a, 14b, 14c and 14d and the data buffers 13a, 13b, 13c and 13d, and the data buffers 13a, 13b, 13c and 13d and the sense amplifiers 12a, 12b, 12c and 12d are respectively connected to one another. Power supply voltages VCC and VSS are applied to the flash memory via external terminals.

In the flash memory, the memory arrays 10a, 10b, 10c and 10d respectively comprise a plurality of electrically erasable and programmable nonvolatile memory cells disposed at points where word lines and bit lines intersect and are divided into the four banks BK0, BK1, BK2 and BK3. The banks BK0, BK1, BK2 and BK3 are capable of respectively performing memory operations such as writing/reading, etc. independently.

Arbitrary memory cells lying in the memory arrays 10a, 10b, 10c and 10d are respectively selected by the X decoders 11a, 11b, 11c and 11d and Y gating/Y decoders 14a, 14b, 14c and 14d. Writing/reading of data is effected on the selected memory cells through the sense amplifiers 12a, 12b, 12c and 12d, data buffers 13a, 13b, 13c and 13d, Y gating/Y decoders 14a, 14b, 14c and 14d and multiplexer 23. Upon the writing/reading, addresses of the selected memory cells, i.e., an X address (row address) is determined by the page address buffer 20 and the bank/X•selector 19, whereas a Y address (column address) is determined by the column address counter 21. The banks BK0, BK1, BK2 and BK3 are selected by the bank/X•selector 19.

Control for the occurrence of timing signals at the writing/reading of data, etc. is controlled by the controller 18. The command decoder 17 includes command buffers of one stage or two or more stages and decodes each command inputted via the input/output terminal I/O and the multiplexer 23. The controller 18 executes various memory operations in accordance with an instruction corresponding to the decoded command. For example, page cache read operations to be explained below are controlled and executed by the controller 18.

A description will next be made of a one-page cache read operation at a one-stage command buffer in the nonvolatile memory apparatus according to the present embodiment with reference to FIGS. 2 through 4. FIGS. 2 through 4 are respectively timing charts showing operations continuous on a time sequence basis as in the case of FIG. 2 to FIG. 3 and FIG. 3 to FIG. 4. In FIGS. 2 through 15, I/O indicates a data signal inputted/outputted through the input/output terminal I/O. BK0 through BK3 respectively indicate operating states of the respective banks, and the period during which the present signal is low in level, indicates that reading of data from the memory arrays 10a, 10b, 10c and 10d to the data buffers 13a, 13b, 13c and 13d via the sense amplifiers 12a, 12b, 12c and 12d is being performed at the respective banks BK0, BK1, BK2 and BK3. R/B indicates a ready/busy signal outputted from the controller 18. The ready/busy signal R/B is capable of having three statuses of (1) whether the following command can be accepted, (2) whether an internal operation based on the previous command is completed, and (3) whether the command buffer is available. Whether the ready/busy signal R/B corresponds to an output indicative of any of the three statuses, can be switched according to the command and determined thereby.

Although not limited to it, the present embodiment will be explained assuming that when the ready/busy signal R/B is high in level, i.e., ready R, it means a state in which the internal operation based on the previous command is being completed or a state in which the command buffer is available and the next command can be accepted. When the ready/busy signal R/B is low in level, i.e., busy B in reverse, it means a state in which an internal operation based on a previous command is not completed, or a state in which the following command cannot be accepted because the command buffer is not available.

Since the ready/busy signal R/B is ready and a command is inputtable during a period of (1) shown in FIG. 2, a read address B0 for the bank BK0 is inputted from the input/output terminal I/O to input a read start command RM. In doing so, the operation for reading from the memory array 10a to the data buffer 13a is started at the bank BK0. During the period in which the data was read from the memory array to the data buffer, the ready/busy signal R/B was conventionally busy and hence the next command could not be accepted.

During a period of (2), the ready/busy signal R/B becomes busy since processing such as the setting of each status register lying inside the chip is performed, in other words, only during a short period taken until the command decoder reads a command stored in the command buffer and the vacancy occurs in the command buffer. After the processing such as the setting of each status register lying inside the chip has been completed, the ready/busy signal R/B becomes ready at once and hence the following command can be accepted.

Since the ready/busy signal R/B is ready and the command is inputtable during a period of (3), a read address B1 for the bank BK1 is inputted from the input/output terminal I/O to input the following read start command RM. At this time, the operation of data reading by the previous command from the memory array 10a to the data buffer 13a is in execution at the bank BK0. Although the read operation was in execution at the bank BK0 and the address/data/command or the like could not be inputted in the prior art, a read command to another bank can be accepted because the ready/busy signal R/B is ready, in the present embodiment.

Since the read start command for the bank BK1 is inputted during the period of (3) and the command buffer caches (fetches therein) the command, the following command cannot be cached (fetched) during a period of (4). In the present embodiment, the cache of a command can be done up to once because the command buffer is one stage. Therefore, the ready/busy signal R/B is busy until the reading from the memory array 10a to the data buffer 13a at the bank BK0 previously inputted with the read address is terminated.

Since the data reading from the memory array 10a to the data buffer 13a at the bank BK0 is completed during a period of (5), the read command for the bank BK1, which has been cached in the command buffer, is automatically started so that reading from the memory array 10b to the data buffer 13b is performed. Since the command buffer is available simultaneously with reading of the bank BK1, the ready/busy signal R/B becomes ready. That is, the fact that the ready/busy signal R/B becomes ready, means that the previously inputted read command is completed upon a cache operation. When a read address B0 for the bank BK0 is inputted from the input/output terminal I/O in response to the ready/busy signal R/B being ready and thereby a buffer read command RB is inputted, data Dout is outputted from the data buffer 13a of the bank BK0 to the outside via the Y gating/Y decoder 14a, the multiplexer 23 and the input/output terminal I/O. In the present embodiment, the period for outputting data from the data buffer to the outside is explained as one longer than the period for reading from the memory array to the data buffer. During the period of (5) in FIG. 2, for example, the reading from the memory array 10b of the bank BK1 to the data buffer 13b is terminated in the course of outputting of the data from the data buffer 13a of the bank BK0 to the outside.

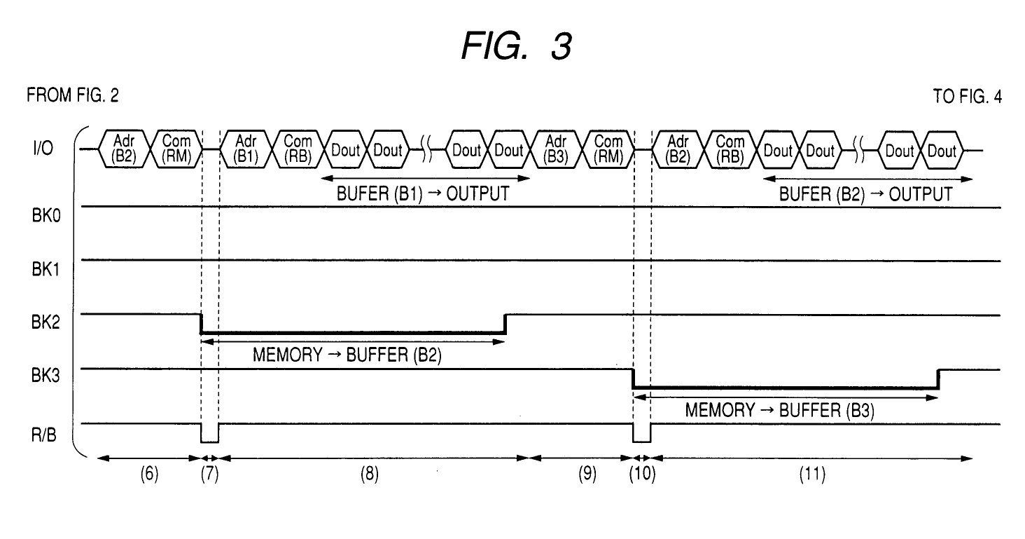

The one-page cache read operation proceeds to FIG. 3. After the reading of data from the data buffer 13a of the bank BK0 to the outside has been completed, a read address B2 for the bank BK2 is inputted from the input/output terminal I/O to input the next read start command RM during a period of (6). In doing so, the operation for reading from the memory array 10c to the data buffer 13c is started at the bank BK2.

During a period of (7), the ready/busy signal R/B becomes busy only in a short period of time in a manner similar to the period of (2). After the completion of processing such as the setting of each status register lying inside the chip, the ready/busy signal R/B becomes ready at once and hence the next command can be accepted.

When a read address B1 for the bank BK1 is inputted from the input/output terminal I/O in response to the ready/busy signal R/B being ready, to input a buffer read command RB, data Dout is outputted from the data buffer 13b of the bank BK1 to the outside via the Y gating/Y decoder 14b, the multiplexer 23 and the input/output terminal I/O during a period of (8).

During a period of (9), after the completion of the data reading from the data buffer 13b of the bank BK1 to the outside, a read address B3 for the bank BK3 is inputted from the input/output terminal I/O to input the next read start command RM. In doing so, the operation for reading from the memory array 10d to the data buffer 13d is started at the bank BK3.

During a period of (10), the ready/busy signal R/B becomes busy only in a short period of time in a manner similar to the periods of (2) and (7). After the completion of the processing such as the setting of each status register lying inside the chip, the ready/busy signal R/B becomes ready at once and hence the next command can be accepted.

When a read address B2 for the bank BK2 is inputted from the input/output terminal I/O in response to the ready/busy signal R/B being ready, to input a buffer read command RB, data Dout is outputted from the data buffer 13c of the bank BK2 to the outside via the Y gating/Y decoder 14c, the multiplexer 23 and the input/output terminal I/O during a period of (11).

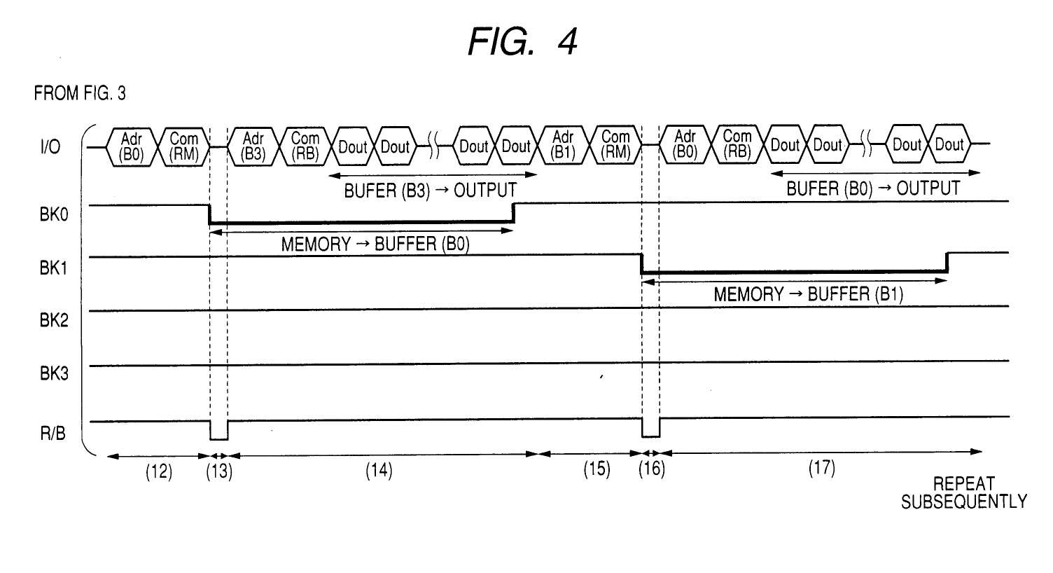

The one-page cache read operation proceeds to FIG. 4. After the reading of data from the data buffer 13c of the bank BK2 to the outside has been completed, a read address B0 for the bank BK0 is inputted from the input/output terminal I/O to input the next read start command RM during a period of (12). In doing so, the operation for reading from the memory array 10a to the data buffer 13a is started at the bank BK0.

During a period of (13), the ready/busy signal R/B becomes busy only in a short period of time in a manner similar to the periods of (2), (7) and (10). After the completion of processing such as the setting of each status register lying inside the chip, the ready/busy signal R/B becomes ready at once and hence the next command can be accepted.

When a read address B3 for the bank BK3 is inputted from the input/output terminal I/O in response to the ready/busy signal R/B being ready, to input a buffer read command RB, data Dout is outputted from the data buffer 13d of the bank BK3 to the outside via the Y gating/Y decoder 14d, the multiplexer 23 and the input/output terminal I/O during a period of (14).

During a period of (15), after the completion of the data reading from the data buffer 13d of the bank BK3 to the outside, a read address B1 for the bank BK1 is inputted from the input/output terminal I/O to input the next read start command RM. In doing so, the operation for reading from the memory array 10b to the data buffer 13b is started at the bank BK1.

During a period of (16), the ready/busy signal R/B becomes busy only in a short period of time in a manner similar to the periods of (2), (7), (10) and (13). After the completion of the processing such as the setting of each status register lying inside the chip, the ready/busy signal R/B becomes ready at once and hence the next command can be accepted.

When a read address B0 for the bank BK0 is inputted from the input/output terminal I/O in response to the ready/busy signal R/B being ready, to input a buffer read command RB, data Dout is outputted from the data buffer 13a of the bank BK0 to the outside via the Y gating/Y decoder 14a, the multiplexer 23 and the input/output terminal I/O during a period of (17).

In like manner subsequently, the output of data from the data buffers of other banks already subjected to the completion of reading to the outside and the input of the following address/command are performed during the reading from the memory arrays 10a, 10b, 10c and 10d to the data buffers 13a, 13b, 13c and 13d while the banks BK0, BK1, BK2 and BK3 are being switched.

In the present embodiment, although not shown in the drawing, when the ready/busy signal R/B is high in level, i.e., ready R, it means a state in which the internal operation based on the previous command is completed and the command buffer is available, and the following command can be accepted. Therefore, since the ready/busy signal R/B is ready even where the reading from the memory array 10b of the bank BK1 to the data buffer 13b is not completed in the course of the period of (5), for example, the input of a read address and the input of a read start command RM to the bank BK2 during the period of (6) of FIG. 3 are made possible. In this case, the reading from the memory array 10c of the bank BK2 to the data buffer 13c thereof is automatically started after the completion of the memory array 10b of the bank BK1 to the data buffer 13b thereof. The ready/busy signal R/B in this case behaves as being ready when the reading from the memory array 10b of the bank BK1 to the data buffer 13b is completed and a vacancy occurs in a command cache.

How to end the one-page cache reading will next be explained with reference to FIG. 5. Since no memory read command is inputted at the end of data reading, the timing in which the previously-inputted command is finished, cannot be determined by the ready/busy signal R/B. Therefore, as shown in FIG. 5, an end command END is prepared and the internal operating state is outputted as for a ready/busy signal R/B, based on the end command END (portion indicated by A in FIG. 5).

When the read address B2 for the bank BK2 is inputted to input the buffer read command RB and the output of the data Dout from the data buffer 13c of the bank BK2 to the outside is early ended, for example, during the period of (11) in FIG. 3, the end command END is inputted subsequently. Consequently, it is determined whether the reading from the memory array 10d to the data buffer 13d is completed at the bank BK3. That is, when the end command END is inputted from the input/output terminal I/O, the ready/busy signal R/B becomes busy (the portion indicated by A in FIG. 5) where no internal operation is completed. When the internal operation is completed, the ready/busy signal R/B becomes ready. With the ready/busy signal R/B becoming ready, the output of data Dout from the data buffer 13d to the outside is enabled at the bank BK3.

Thus, according to the nonvolatile memory apparatus of the present embodiment, the time provided for reading from the memory array visible to the outside to the data buffer upon reading of such high-volume data as to be taken over a plurality of pages is equivalent to only processing relative to the first read command. Since it is invisible to the outside subsequently to the second time, throughput can be improved.

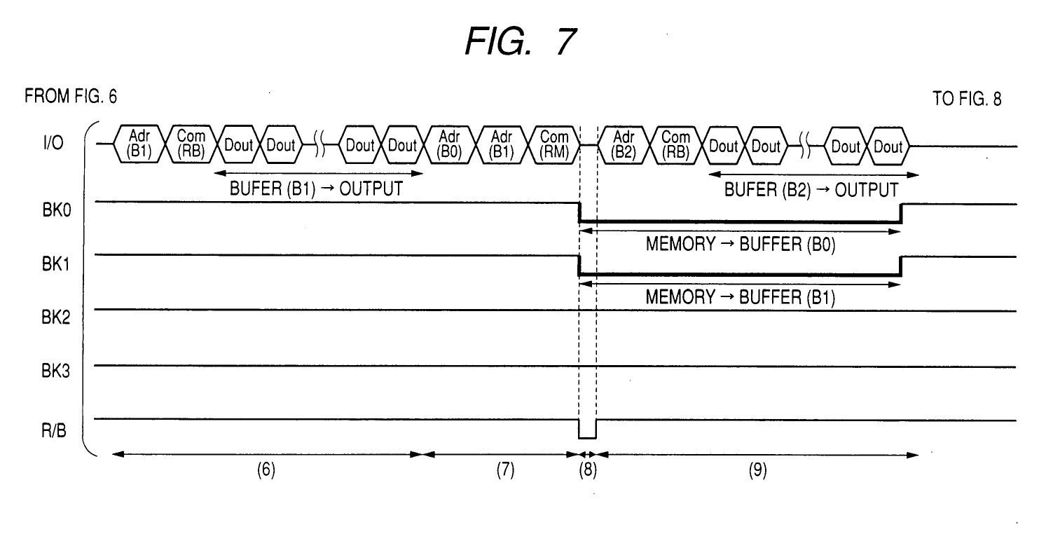

A description will next be made of a two-page cache read operation at a one-stage command buffer in the nonvolatile memory apparatus according to the present embodiment with reference to FIGS. 6 through 9. FIGS. 6 through 9 are respectively timing charts at the time that addresses and read commands corresponding to two pages are cached in a four-bank configuration. The number of the banks at which the reading operations according to the previous embodiment are simultaneously performed, is one, whereas the number of banks at which the reading operations according to the present embodiment are simultaneously performed, is two. Incidentally, FIGS. 6 through 9 are respectively timing charts showing operations continuous on a time sequence basis as in the case of FIG. 6 to FIG. 7, FIG. 7 to FIG. 8 and FIG. 8 to FIG. 9.

Since a ready/busy signal R/B is ready and a command is inputtable during a period of (1) shown in FIG. 6, a read address B0 for the bank BK0 and a read address B1 for the bank BK1 are inputted from the input/output terminal I/O to input a read start command RM. In doing so, the operations of reading from the memory arrays 10a and 10b to the data buffers 13a and 13b are started at the banks BK0 and BK1.

During a period of (2), the ready/busy signal R/B becomes busy since processing such as the setting of each status register lying inside the chip is performed, in other words, only during a short period taken until the command decoder reads a command stored in the command buffer and the vacancy occurs in the command buffer. After the processing such as the setting of each status register lying inside the chip has been completed, the ready/busy signal R/B becomes ready at once and hence the following command can be accepted.

Since the ready/busy signal R/B is ready and the command is inputtable during a period of (3), a read address B2 for the bank BK2 and a read address B3 for the bank BK3 are inputted from the input/output terminal I/O to input the following read start command RM. At this time, the operations of data reading by the previous commands from the memory arrays 10a and 10b to the data buffers 13a and 13b are in execution at the banks BK0 and BK1.

Since the read start command for the banks BK2 and BK3 is inputted during the period of (3) and the command buffer caches (fetches therein) the command, the following command cannot be cached (fetched) during a period of (4). In the present embodiment, the cache of a command can be done only once because the command buffer is one stage. Therefore, the ready/busy signal R/B is busy until the reading from the memory arrays 10a and 10b to the data buffers 13a and 13b at the banks BK0 and BK1 previously inputted with the read addresses is terminated.

Since the data reading from the memory arrays 10a and 10b to the data buffers 13a and 13b at the banks BK0 and BK1 is completed during a period of (5), the read commands for the banks BK2 and BK3, which have been cached in the command buffer, are automatically started so that reading from the memory arrays 10c and 10d to the data buffers 13c and 13d is performed. Since the command buffer is available simultaneously with reading of the banks BK2 and BK3, the ready/busy signal R/B becomes ready. When a read address B0 for the bank BK0 is inputted from the input/output terminal I/O in response to the ready/busy signal R/B being ready and thereby a buffer read command RB is inputted, data Dout is outputted from the data buffer 13a of the bank BK0 to the outside via the Y gating/Y decoder 14a, the multiplexer 23 and the input/output terminal I/O.

The two-page cache read operation proceeds to FIG. 7. During a period of (6), when a read address B1 for the bank BK1 is inputted from the input/output terminal I/O to input a buffer read command RB, data Dout is outputted from the data buffer 13b of the bank BK1 to the outside via the Y gating/Y decoder 14b, the multiplexer 23 and the input/output terminal I/O.

During a period of (7), after the completion of the data reading from the data buffer 13b of the bank BK1 to the outside, a read address B0 for the bank BK0 and a read address B1 for the bank BK1 are inputted from the input/output terminal I/O to input the next read start command RM. In doing so, the operations for reading from the memory arrays 10a and 10b to the data buffers 13a and 13b are started.

Although the read commands are inputted at both of the banks BK0 and BK1 during the period of (7), the read command for the read address B0 of the bank BK0 may be inputted.

During a period of (8), the ready/busy signal R/B becomes busy only in a short period of time in a manner similar to the period of (2). After the completion of processing such as the setting of each status register lying inside the chip, the ready/busy signal R/B becomes ready immediately and hence the next command can be accepted.

During a period of (9), when a read address B2 for the bank BK2 is inputted from the input/output terminal I/O in response to the ready/busy signal R/B being ready, to input a buffer read command RB, data Dout is outputted from the data buffer 13c of the bank BK2 to the outside via the Y gating/Y decoder 14c, the multiplexer 23 and the input/output terminal I/O.

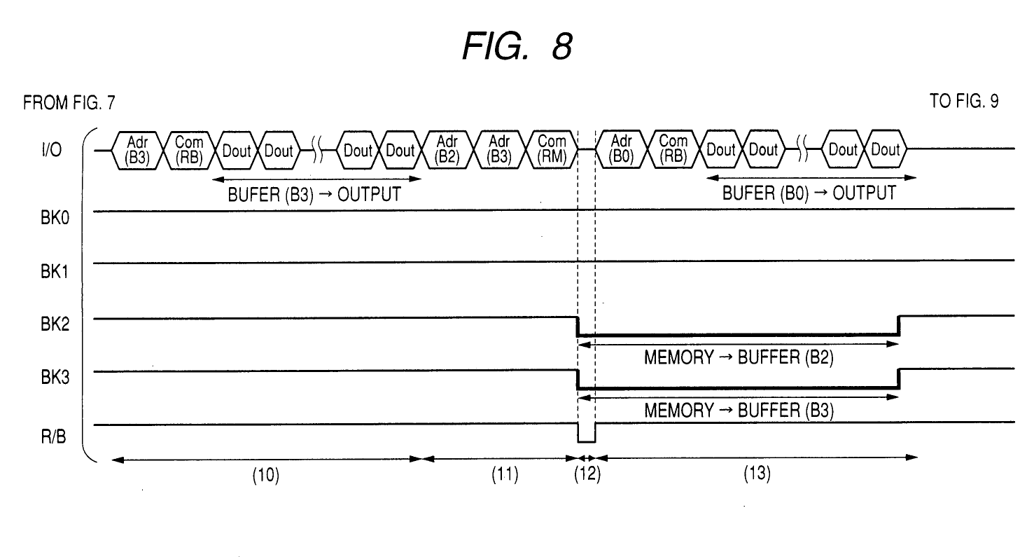

The two-page cache read operation proceeds to FIG. 8. When a read address B3 for the bank BK3 is inputted from the input/output terminal I/O to input a buffer read command RB after the completion of data reading from the data buffer 13c of the bank BK2 to the outside, data Dout is outputted from the data buffer 13d of the bank BK3 to the outside via the Y gating/Y decoder 14d, the multiplexer 23 and the input/output terminal I/O during a period of (10).

After the reading of data from the data buffer 13d of the bank BK3 to the outside has been completed, a read address B2 for the bank BK2 and a read address B3 for the bank BK3 are inputted from the input/output terminal I/O to input the next read start command RM during a period of (11). In doing so, the operations for reading from the memory arrays 10c and 10d to the data buffers 13c and 13d are started at the banks BK2 and BK3.

During a period of (12), the ready/busy signal R/B becomes busy only in a short period of time in a manner similar to the periods of (2) and (8). After the completion of the processing such as the setting of each status register lying inside the chip, the ready/busy signal R/B becomes ready at once and hence the next command can be accepted.

When a read address B0 for the bank BK0 is inputted from the input/output terminal I/O in response to the ready/busy signal R/B being ready, to input a buffer read command RB, data Dout is outputted from the data buffer 13a of the bank BK0 to the outside via the Y gating/Y decoder 14a, the multiplexer 23 and the input/output terminal I/O during a period of (13).

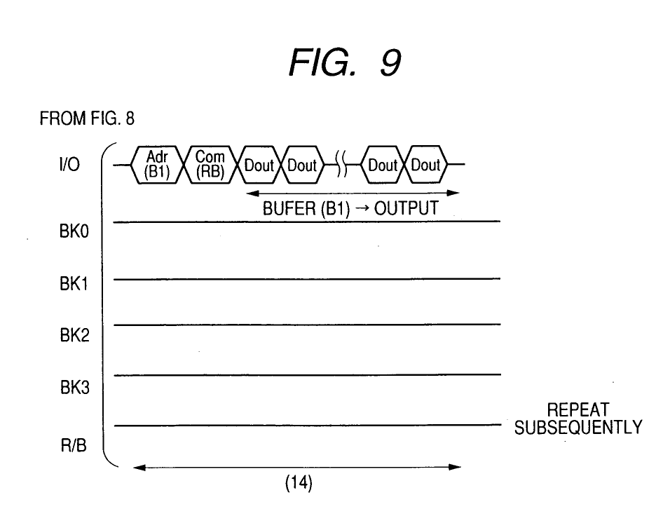

The two-page cache read operation proceeds to FIG. 9. When a read address B1 for the bank BK1 is inputted from the input/output terminal I/O to input a buffer read command RB after the completion of data reading from the data buffer 13a of the bank BK0 to the outside, data Dout is outputted from the data buffer 13b of the bank BK1 to the outside via the Y gating/Y decoder 14b, the multiplexer 23 and the input/output terminal I/O during a period of (14).

In a manner similar to above subsequently, the output of data from the data buffers of other banks already subjected to the completion of reading to the outside and the input of the following address/command are performed during the two bank-by-two bank reading from the memory arrays 10a, 10b, 10c and 10d to the data buffers 13a, 13b, 13c and 13d while the banks BK0, BK1, BK2 and BK3 are being switched.

In the present embodiment, although not shown in the drawing, when the ready/busy signal R/B is high in level, i.e., ready R, it means a state in which the internal operation based on the previous command is completed and the command buffer is available, and the following command can be accepted. Therefore, since the ready/busy signal R/B is ready even where the reading from the memory arrays 10c and 10d of the banks BK2 and BK3 to the data buffers 13c and 13d is not completed in the course of the periods of (5) and (6), for example, the input of a read address and the input of a read start command RM to the banks BK0 and BK1 during the period of (7) of FIG. 7 are made possible. In this case, the reading from the memory arrays 10a and 10b of the banks BK0 and BK1 to the data buffers 13a and 13b thereof is automatically started at the banks BK0 and BK1 after the completion of reading from the memory arrays 10c and 10d of the banks BK2 and BK3 to the data buffers 13c and 13d thereof. The ready/busy signal R/B in this case behaves as being ready when the reading from the memory arrays 10c and 10d of the banks BK2 and BK3 to the data buffers 13c and 13d thereof is completed and a vacancy occurs in a command cache.

How to end the two-page cache reading will next be explained with reference to FIG. 10. Since no memory read command is inputted at the end of data reading, the timing in which the previously-inputted command is finished, cannot be determined by the ready/busy signal R/B. Therefore, as shown in FIG. 10, an end command END is prepared and the internal operating state is outputted as for a ready/busy signal R/B, based on the end command END (portion indicated by A in FIG. 10).

When the read address B1 for the bank BK1 is inputted to input the buffer read command RB and the output of the data Dout from the data buffer 13b of the bank BK1 to the outside is early ended, for example, during the period of (14) in FIG. 9, the end command END is inputted subsequently. Consequently, it is determined whether the reading from the memory arrays 10c and 10d to the data buffers 13c and 13d is completed at the banks BK2 and BK3. That is, when the end command END is inputted from the input/output terminal I/O, the ready/busy signal R/B becomes busy (the portion indicated by A in FIG. 10) where no internal operation is completed. When the internal operation is completed, the ready/busy signal R/B becomes ready. With the ready/busy signal R/B becoming ready, the output of data Dout from the data buffers 13c and 13d to the outside at the banks BK2 and BK3 is enabled.

Thus, according to the two-page cache reading of the present embodiment, the time provided for reading from the memory array visible to the outside to the data buffer is equivalent to only processing relative to the first read command in a manner similar to the one-page cache reading of the previous embodiment. Since it is invisible to the outside subsequently to the second time, throughput can be improved.

When the reading from the memory array to the data buffer is not completed within the time required to output the data from the data buffer to the outside upon the one-page cache reading of the above embodiment, a latency time occurs until the reading from the memory array to the data buffer is completed, so that throughput is degraded. In such a case, the two-page cache reading according to the present embodiment is used. Thus, since the time necessary for reading from the memory arrays to the data buffers becomes effectively ½ with respect to the one-page cache, throughput can further be improved.

A description will next be made of a one-page cache read operation at two-stage command buffers in the nonvolatile memory apparatus according to the present embodiment with reference to FIGS. 11 and 12. FIGS. 11 and 12 are respectively timing charts showing operations continuous on a time sequence basis as in the case of FIG. 11 to FIG. 12.

Since a ready/busy signal R/B is ready and a command is inputtable during a period of (1) shown in FIG. 11, a read address B0 for the bank BK0 is inputted from the input/output terminal I/O to input a read start command RM. In doing so, the operation for reading from the memory array 10a to the data buffer 13a is started at the bank BK0.

During a period of (2), the ready/busy signal R/B becomes busy since processing such as the setting of each status register lying inside the chip is performed, in other words, only during a short period taken until the command decoder reads a command stored in each command buffer and the vacancy occurs in the command buffer. After the processing such as the setting of each status register lying inside the chip has been completed, the ready/busy signal R/B becomes ready at once and hence the following command can be accepted.

Since the ready/busy signal R/B is ready and the command is inputtable during a period of (3), a read address B1 for the bank BK1 is inputted from the input/output terminal I/O to input the following read start command RM. At this time, the operation of data reading by the previous command from the memory array 10a to the data buffer 13a is in execution at the bank BK0.

During a period of (4), the ready/busy signal R/B becomes busy only in a short period of time in a manner similar to the period of (2).

Since the ready/busy signal R/B is ready and the command is inputtable during a period of (5), a read address B2 for the bank BK2 is inputted from the input/output terminal I/O to input the following read start command RM. At this time, the operation of data reading by the previous command from the memory array 10a to the data buffer 13a is in execution at the bank BK0.

Since the read start command for the bank BK2 is inputted during the period of (5) and each command buffer caches (fetches therein) the command, the following command cannot be cached (fetched) during a period of (6). In the present embodiment, the cache of a command can be done only twice because the command buffers are two stages. Therefore, the ready/busy signal R/B is busy until the reading from the memory array 10a to the data buffer 13a at the bank BK0 previously inputted with the read address is terminated.

Since the reading from the memory array 10a to the data buffer 13a at the bank BK0 is completed during a period of (7), the read command for the bank BK1, which has been cached in the corresponding command buffer, is automatically started so that reading from the memory array 10b to the data buffer 13b is performed. Since the command buffers are available simultaneously with reading of the bank BK1, the ready/busy signal R/B becomes ready. That is, the fact that the ready/busy signal R/B becomes ready, means that the previously inputted read command is completed upon a cache operation. When the read address B0 for the bank BK0 is inputted from the input/output terminal I/O in response to the ready/busy signal R/B being ready and thereby a buffer read command RB is inputted, data Dout is outputted from the data buffer 13a of the bank BK0 to the outside via the Y gating/Y decoder 14a, the multiplexer 23 and the input/output terminal I/O. During the period of (7) in FIG. 11, the reading from the memory array 10b of the bank BK1 to the data buffer 13b is terminated in the course of outputting of data from the data buffer 13a of the bank BK0 to the outside. When the reading from the memory array 10b of the bank BK1 to the data buffer 13b thereof is completed, a read command for the bank BK2, which has been cached in the corresponding command buffer, is automatically started so that reading from the memory array 10c to the data buffer 13c is performed.

The two-page cache read operation proceeds to FIG. 12. During a period of (8), after the completion of data reading from the data buffer 13a of the bank BK0 to the outside, a read address B3 for the bank BK3 is inputted from the input/output terminal I/O to input the next read start command RM.

During a period of (9), the ready/busy signal R/B becomes busy only in a short period of time in a manner similar to the periods of (2) and (4).

When a read address B1 for the bank BK1 is inputted from the input/output terminal I/O in response to the ready/busy signal R/B being ready, to input a buffer read command RB, data Dout is outputted from the data buffer 13b of the bank BK1 to the outside via the Y gating/Y decoder 14b, the multiplexer 23 and the input/output terminal I/O during a period of (10). When the reading from the memory array 10c of the bank BK2 to the data buffer 13c is completed, a read command for the bank BK3, which has been cached in the corresponding command buffer, is automatically started so that reading from the memory array 10d to the data buffer 13d is carried out.

During a period of (11), after the completion of the data reading from the data buffer 13b of the bank BK1 to the outside, a read address B0 for the bank BK0 is inputted from the input/output terminal I/O to input the next read start command RM.

During a period of (12), the ready/busy signal R/B becomes busy only in a short period of time in a manner similar to the periods of (2), (4) and (9).

When a read address B2 for the bank BK2 is inputted from the input/output terminal I/O in response to the ready/busy signal R/B being ready, to input a buffer read command RB, data Dout is outputted from the data buffer 13c of the bank BK2 to the outside via the Y gating/Y decoder 14c, the multiplexer 23 and the input/output terminal I/O during a period of (13). When the reading from the memory array 10d of the bank BK3 to the data buffer 13d is completed, a read command for the bank BK0, which has been cached in the corresponding command buffer, is automatically started so that reading from the memory array 10a to the data buffer 13a is carried out.

In a manner similar to above subsequently, the output of data from the data buffers of other banks already subjected to the completion of reading to the outside and the input of the following address/command are performed during the reading from the memory arrays 10a, 10b, 10c and 10d to the data buffers 13a, 13b, 13c and 13d while the banks BK0, BK1, BK2 and BK3 are being switched.

Thus, according to the present embodiment, throughput can further be improved owing to the use of the two-stage command buffers.

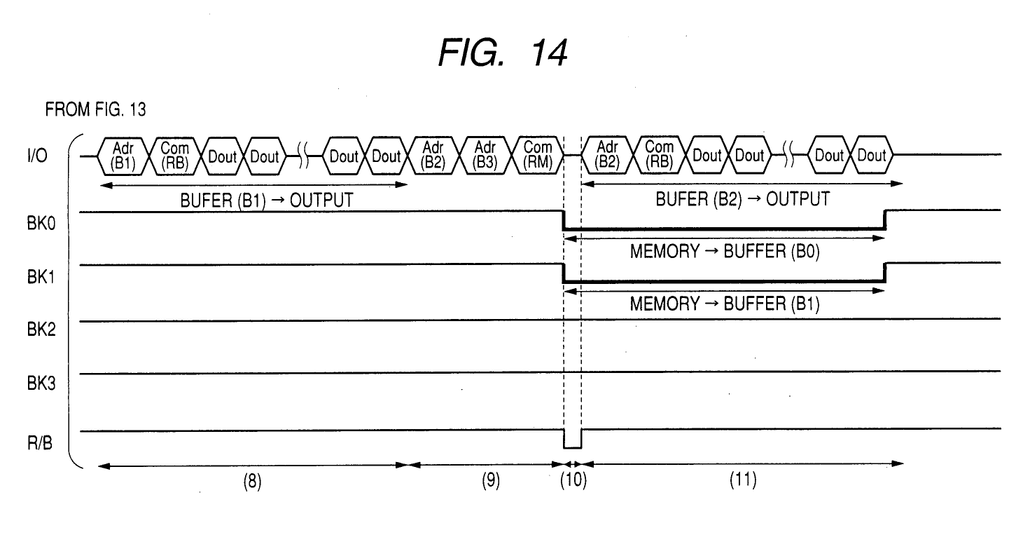

A description will next be made of a two-page cache read operation at two-stage command buffers in the nonvolatile memory apparatus according to the present embodiment with reference to FIGS. 13 and 14. FIGS. 13 and 14 are respectively timing charts at the time that addresses and read commands corresponding to two pages are cached in a four-bank configuration. The number of the banks at which the reading operations according to the previous embodiment shown in FIGS. 11 and 12 are simultaneously performed, is one, whereas the number of banks at which the reading operations according to the present embodiment are simultaneously performed, is two. Incidentally, FIGS. 13 and 14 are respectively timing charts showing operations continuous on a time sequence basis as in the case of FIG. 13 to FIG. 14.

Since a ready/busy signal R/B is ready and a command is inputtable during a period of (1) shown in FIG. 13, a read address B0 for the bank BK0 and a read address B1 for the bank BK1 are inputted from the input/output terminal I/O to input a read start command RM. In doing so, the operations for reading from the memory arrays 10a and 10b to the data buffers 13a and 13b are started at the banks BK0 and BK1.

During a period of (2), the ready/busy signal R/B becomes busy since processing such as the setting of each status register lying inside the chip is performed, in other words, only during a short period taken until the command decoder reads a command stored in each command buffer and the vacancy occurs in the command buffer.

Since the ready/busy signal R/B is ready and the command is inputtable during a period of (3), a read address B2 for the bank BK2 and a read address B3 for the bank BK3 are inputted from the input/output terminal I/O to input the following read start command RM. At this time, the operations of data reading by the previous command from the memory arrays 10a and 10b to the data buffers 13a and 13b are in execution at the banks BK0 and BK1.

During a period of (4), the ready/busy signal R/B becomes busy only in a short period of time in a manner similar to the period of (2).

Since the ready/busy signal R/B is ready and a command is inputtable during a period of (5) because the command buffers are configured in two stages, a read address B0 for the bank BK0 and a read address B1 for the bank BK1 are inputted from the input/output terminal I/O to input the next read start command RM. When the reading from the memory arrays 10a and 10b of the banks BK0 and BK1 to the data buffers 13a and 13b is completed, read commands for the banks BK2 and BK3, which have been cached in the command buffers, are automatically started so that reading from the memory arrays 10c and 10d to the data buffers 13c and 13d is carried out.

During a period of (6), the ready/busy signal R/B becomes busy only in a short period of time in a manner similar to the periods of (2) and (4). Since the command buffers are available at this time, the ready/busy signal R/B becomes ready immediately after the completion of processing such as the setting of each status register lying inside the chip, and hence the next command can be accepted.

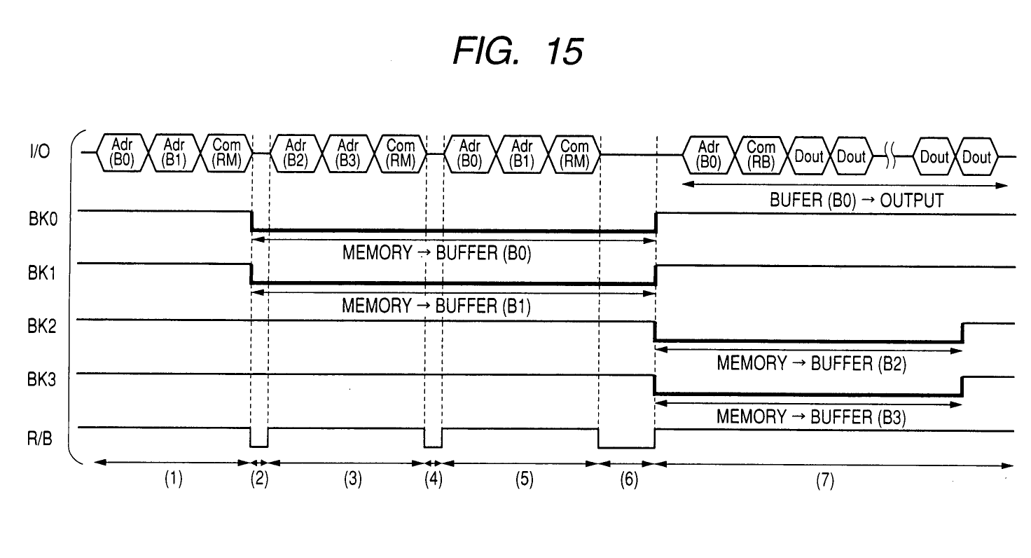

When time is taken to perform the reading from the memory arrays 10a and 10b of the banks BK0 and BK1 to the data buffers 13a and 13b thereof during the periods of (5) and (6), the time at which the ready/busy signal R/B becomes busy, becomes long as shown in FIG. 15.

During a period of (7), when a read address B0 for the bank BK0 is inputted from the input/output terminal I/O in response to the ready/busy signal R/B being ready, to input a buffer read command RB, data Dout is outputted from the data buffer 13a of the bank BK0 to the outside via the Y gating/Y decoder 14a, the multiplexer 23 and the input/output terminal I/O. During the period of (7) in FIG. 13, the reading from the memory arrays 10c and 10d of the banks BK2 and BK3 to the data buffers 13c and 13d is terminated in the course of outputting of data from the data buffer 13a of the bank BK0 to the outside.

The two-page cache read operation proceeds to FIG. 14. When a read address B1 for the bank BK1 is inputted from the input/output terminal I/O to input a buffer read command RB, data Dout is outputted from the data buffer 13b of the bank BK1 to the outside via the Y gating/Y decoder 14b, the multiplexer 23 and the input/output terminal I/O during a period of (8).

After the reading of data from the data buffer 13b of the bank BK1 to the outside has been completed, a read address B2 for the bank BK2 and a read address B3 for the bank BK3 are inputted from the input/output terminal I/O to input the next read start command RM during a period of (9). In doing so, the operations for reading from the memory arrays 10a and 10b to the data buffers 13a and 13b are started at the banks BK0 and BK1.

Incidentally, during the periods of (8) and (9), the operations for reading from the memory arrays 10a and 10b to the data buffers 13a and 13b at the following banks BK0 and BK1 are not started until the output of the data Dout from the data buffers 13a and 13b of the banks BK0 and BK1 to the outside is completed. In FIG. 14, the output of data Dout from the data buffers 13a and 13b of the banks BK0 and BK1 to the outside is recognized as being completed by the read start command RM for the banks BK2 and BK3. The operations for reading from the memory arrays 10a and 10b of the following banks BK0 and BK1 to the data buffers 13a and 13b are started.

During a period of (10), the ready/busy signal R/B becomes busy only in a short period of time in a manner similar to the periods of (2), (4) and (6).

When a read address B2 for the bank BK2 is inputted from the input/output terminal I/O in response to the ready/busy signal R/B being ready, to input a buffer read command RB, data Dout is outputted from the data buffer 13c of the bank BK2 to the outside via the Y gating/Y decoder 14c, the multiplexer 23 and the input/output terminal I/O during a period of (11).

In a manner similar to above subsequently, the output of data from the data buffers of other banks already subjected to the completion of reading to the outside and the input of the following address/command are performed during the two bank-by-two bank reading from the memory arrays 10a, 10b, 10c and 10d to the data buffers 13a, 13b, 13c and 13d while the banks BK0, BK1, BK2 and BK3 are being switched.

Further, determining whether the status outputted by the ready/busy signal R/B corresponds to any of the three statuses referred to above, is enabled by providing a status register unillustrated in FIG. 1 in the controller 18, storing information indicative of the status of the ready/busy signal R/B in the status register and reading the contents of the status register by a status read command.

Furthermore, assuming that the end command END described in FIG. 5 or the like is stored in the corresponding command buffer and command processing is executed in order of input commands, the end command END can be outputted to the outside only during a period up to the completion of the finally-processed read processing (period (A) of FIG. 5).

However, even though commands that do not start execution of other processing, exist, the processing of the end command END may be executed in preference to those immediately when the end command END is inputted, without executing the command processing in order of the inputted commands. Described specifically, when one attempts to perform such control shown in FIGS. 2 through 5 where command buffers are provided in plural stages, the completion of the period of (4) in FIG. 2 becomes unknown. Even in such a case, it is possible to know or recognize the completion of the period of (4) by inputting the end command END after the input (period of (3) in FIG. 2) of a read command having designated the address B1 of the bank BK1.

With the use of the two-page cache reading by the present embodiment, the time necessary for reading from each memory array to each data buffer becomes effectively ½ with respect to the one-page cache, thereby making it possible to further improve throughput.

While the invention made above by the present inventors has been described specifically on the basis of the preferred embodiment, the present invention is not limited to the embodiment referred to above. It is needless to say that various changes can be made thereto without the scope not departing from the gist thereof.

Although the above embodiment has explained the memory's read operation, for example, the present invention is not limited to it but is applicable even to a memory's write operation. The reading and writing of the memory can also be performed in a multiplexed form. That is, a read command that has designated an arbitrary bank is inputted from outside, and a write command that has designated other bank is inputted from outside while reading from a memory array of the arbitrary bank to its corresponding data buffer is being performed, whereby writing into the data buffer can also be preformed.

Although the above embodiment has explained the nonvolatile memory such as the flash memory, the present invention is not limited to it. The present invention is applicable even to other memories such as a DRAM, a SRAM, etc.

The invention disclosed in the present application is applicable to a nonvolatile memory apparatus.

What is claimed is:

1. A nonvolatile memory apparatus comprising:
a plurality of banks which respectively have a plurality of nonvolatile memory cells, each of which is electrically erasable data and is electrically programmable data, and which are capable of memory operation independently respectively; and
a control circuit capable of inputting a read command having designated a second bank from outside during performing a read operation for reading data from a memory cell in the first bank in response to inputting the read command having designated a first bank from outside.

2. A nonvolatile memory apparatus comprising:
a plurality of banks which respectively have a plurality of nonvolatile memory cells, each of which is electrically erasable data and is electrically programmable data, and which are capable of memory operation independently respectively, each of said banks respectively having a buffer which temporarily store data for writing data to a memory cell or for reading data from the memory cell; and
a controller capable of inputting a read command having designated a second bank from outside during performing an operation for reading data from a memory cell in a first bank to a corresponding buffer of the first bank in response to the read command having designated the first bank.

3. The nonvolatile memory apparatus according to claim 2, wherein the operation in response to the read command includes a first operation for reading from the memory cell to the corresponding buffer and a second operation for reading from the corresponding buffer to the outside.

4. The nonvolatile memory apparatus according to claim 3, wherein said controller is capable of controlling to perform said first operation in response to the read command having designated the second bank during performing said second operation in response to the read command having designated the first bank.

5. A nonvolatile memory apparatus comprising:
a plurality of banks which respectively have a plurality of nonvolatile memory cells, each of which is electrically erasable data and electrically programmable data, and which are capable of memory operation independently respectively, each of said banks having buffer which temporarily store data for writing to a memory cell or for reading data from the memory cell; and
a controller capable of inputting a write command having designated a second bank from outside during performing an operation for reading data from a memory cell in a first bank to a corresponding buffer of the first bank in response to a read command having designated the first bank.

6. A nonvolatile memory apparatus comprising:
a plurality of banks which respectively have a plurality of memory cells and are capable of memory operation independently respectively; wherein each of said banks respectively having a buffer which temporarily store data for writing data to a memory cell or for reading data from the memory cell; and
a controller capable of inputting a read command accompanied with a second address for designating a second bank from outside while performing an operation for reading data from the memory cell in a first bank to a corresponding buffer of the first bank in response to the read command accompanied with a first address for designating the first bank.

7. A nonvolatile memory apparatus comprising:
a control circuit;
an input/output terminal; and
a nonvolatile memory section,
wherein said control circuit, said input/output terminal and said nonvolatile memory section are arranged on one semiconductor substrate,
wherein the nonvolatile memory section includes a plurality of memory arrays and data buffers corresponding to the memory arrays, and
wherein the control circuit receives a read operation instruction having designated a first memory array via the input/output terminal, outputs a first signal via the input/output terminal during a first period, and thereafter is capable of receiving a read operation instruction having designated a second memory array different from the first memory array while data is read from the first memory array into the corresponding data buffer of the first memory array.

8. The nonvolatile memory apparatus according to claim 7,
wherein the control circuit includes a command buffer,
wherein the command buffer temporarily stores an operation instruction received via the input/output terminal until starting an operation in response to the operation instruction by the control circuit, and
wherein the first period, in which the first signal is outputted via the input/output terminal, corresponds to a period in which the read operation instruction having designated the first memory array is temporarily stored in the command buffer.

9. The nonvolatile memory apparatus according to claim 8,
wherein the control circuit is capable of receiving a status output operation instruction via the input/output terminal, and outputs the first signal via the input/output terminal while data is read from the first memory array into the corresponding data buffer of the first memory array in response to receiving the status output operation instruction.

10. The nonvolatile memory apparatus according claims 8,
wherein the control circuit is capable of starting reading data from the second memory array into the corresponding data buffer of the second memory array after completion of reading data from the first memory array into the corresponding data buffer of the first memory array, and
wherein the control circuit is capable of outputting the data read from the corresponding data buffer of the first memory array via the input/output terminal while the data is read from the second memory array into the corresponding data buffer of the second memory array.

11. A nonvolatile memory apparatus comprising:
a control circuit;
an input/output terminal; and
a nonvolatile memory section,
wherein said control circuit, said input/output terminal and said nonvolatile memory section are arranged on one semiconductor substrate,
wherein the nonvolatile memory section includes a plurality of memory arrays and a plurality of data buffers corresponding to the memory arrays,
wherein the control circuit includes a command buffer,
wherein the command buffer is capable of storing arbitrary one of operation instructions, which includes a read operation instruction, via the input/output terminal,
wherein the read operation instruction comprises an address part and an operation designation part, and the address part is capable of including addresses for designating one or plural memory arrays,
wherein the control circuit receives a read operation instruction accompanied with the address part for designating a first memory array and a second memory array, and thereafter is capable of receiving a read operation instruction accompanied with the address part for designating a third memory array and a fourth memory array during reading data from the first memory array to the data buffer corresponding to the first memory array and reading data from the second memory array to the data buffer corresponding to the second memory array, and
wherein when the operation instruction is capable of being stored in the command buffer, the control circuit outputs a first status signal to the input/output terminal, and when the operation instruction is not capable of being stored therein, the control circuit outputs a second status signal to the input/output terminal.

12. The nonvolatile memory apparatus according to claim 11,
wherein the command buffer is capable of storing a first operation instruction received via the input/output terminal, and thereafter is capable of storing a second operation instruction via the input/output terminal in response to starting operation corresponding to the first operation instruction by the control circuit.

13. The nonvolatile memory apparatus according to claim 11,
wherein the control circuit is capable of outputting, via the input/output terminal, data stored into either the data buffer corresponding to the first memory array or the data buffer corresponding to the first memory array after completion of operation in response to the read operation instruction accompanied with the address part for designating the first memory array and the second memory array, during performing an operation in response to the read operation instruction accompanied with the address part for designating the third memory array and a fourth memory.

14. The nonvolatile memory apparatus according to claim 13,
wherein the operation instruction further includes a status output operation instruction,
wherein the status output operation instruction comprises an operation designation part, and
wherein the control circuit is capable of outputting one of a first state signal, which indicates performing one of writing operation and reading operation in one or more memory arrays, and a second state signal, which indicates not performing both of the writing operation and the reading operation in all of the memory arrays, instead of outputting signal indicating whether the operation instruction capable of stored in the command buffer or not.
